(19) United States
(12) Patent Application Publication
(10) Pub. No.: US 2026/0289691 A1
(43) Pub. Date: Sep. 24, 2026

(54) METHOD FOR OPTIMIZING OPEN-PIT MINE LIMITS WITH SIMULTANEOUS CONSIDERATION OF MINING CARBON EMISSIONS AND SLOPE SAFETY

(71) Applicant: Northeastern University, Shenyang (CN)

(72) Inventors: Xiaowei GU, Shenyang (CN); Zhenguo ZHU, Shenyang (CN); Xiaochuan XU, Shenyang (CN); Xiaowei GE, Shenyang (CN); Fengdan WANG, Shenyang (CN); Jianping LIU, Shenyang (CN); Qing WANG, Shenyang (CN); Hao WANG, Shenyang (CN)

(21) Appl. No.: 19/670,070

(22) Filed: May 7, 2026

(51) Int. Cl. G06Q 50/02; G06T 17/00

(52) U.S. Cl. CPC G06Q 50/02; G06T 17/00

(57) ABSTRACT

The present disclosure pertains to a method for optimizing open-pit mine limits with simultaneous consideration of mining carbon emissions and slope safety, comprising the following steps: establishing a three-dimensional model of the mine; establishing a carbon emission calculation model for open-pit mining; determining rock indices and rock types of the mine; dividing the mining area into geological zones, determining an acceptable slope angle range for each zone, and forming slope angle combination schemes; calculating the final limit under each slope angle combination one by one; obtaining a sequence of three-dimensional geological models of the limits; calculating the slope instability probability for each zone; calculating the carbon emissions for each limit; dividing the limit results according to the acceptable slope instability probability indices, and directly calculating the benefit evaluation indices for results that meet the requirement; designing reinforcement schemes for results that do not meet the slope instability probability index.

### TECHNICAL FIELD

The present disclosure pertains to the field of open-pit mining limits design technology, particularly to a method for optimizing open-pit mine limits with simultaneous consideration of mining carbon emissions and slope safety.

### BACKGROUND

Open-pit mining offers advantages in the development of shallow mineral resources, including low cost, strong safety, and high efficiency. In the short term, it remains the primary method of mineral resource development in China. The delineation of the open-pit limit determines not only the volume of ore mined and waste rock stripped, but also determines the impact of the entire activity on the ecological environment, as well as the safety and stability of the slope throughout the mining process. Particularly in medium to large-scale open-pit mines, even minor adjustments in limit design can lead to significant changes in critical parameters such as stripping ratio, ore volume, and slope geometry, thereby affecting mining benefits, slope stability, and ecological environmental damage.

Conventional open-pit limit design and optimization processes are focused on ore volume (mining efficiency) as the optimization objective. Meanwhile, the ecological environmental issues caused by open-pit mining and the slope safety and stability problems induced by such operations have been studied independently. This approach prevents the integrated consideration of mining efficiency, ecological environment, and slope safety during the mine planning and design stage, making it impossible to achieve an optimal solution under multi-objective conditions.

Currently, existing open-pit mine limit optimization methods involve integrating either mining benefits with ecological value losses or mining benefits with slope safety costs into the limit design. These approaches achieve dual-objective optimization of open-pit mine limits and advance limit optimization design methods towards safer, greener and more efficient practices. Nevertheless, because the benefits derived from mining, the ecological environmental impacts caused by mining, and the slope instability induced by mining belong to three distinct dimensions, each with different quantitative methods and indicators, no comprehensive method currently exists that incorporates all three optimization objectives simultaneously, namely, the benefits obtained from open-pit mining, the environmental problems arising from mining activities, and the safety and stability of slopes under mining disturbance. Furthermore, in limit optimization methods that consider slope safety, slope morphology control is typically achieved by altering the angle or height at a specific point of a fixed slope body. This approach cannot achieve random variations in slope morphology, which often leads to conflicts between the slope geometry optimization results and the limit optimization results.

### SUMMARY

In view of the shortcomings of existing technologies, the present disclosure provides a method for optimizing open-pit mine limits with simultaneous consideration of mining carbon emissions and slope safety. The ecological environmental problems caused by mining are quantified in the form of comprehensive carbon emissions, and the stability degree of the limit slope is quantified using an instability probability index. Combined with the mining benefits of the limit, a comprehensive open-pit mine limits optimization method is established. This method considers ecological and environmental issues, as well as slope stability, induced by mining in a comprehensive and simultaneous manner, thereby promoting the sustainable development of open-pit mining.

To achieve the above objective, the present disclosure provides the following solution:

A method for optimizing open-pit mine limits with simultaneous consideration of mining carbon emissions and slope safety, including:
step 1: based on geological drilling data, establishing a three-dimensional geological model, an ore body model, and a grade model of a mine, respectively;
step 2: determining a vegetation distribution and a soil structure around a mining area based on a field investigation method, and establishing a carbon emission calculation model for open-pit mining in combination with mining economic and technical parameters;
step 3: determining strength indices of mine rocks based on field point load tests and laboratory tests, establishing distribution functions for each strength index, obtaining a distribution of rock mass structural planes, and determining a rock mass structure type;
step 4: dividing the rock mass in the mining area into different zones according to slope instability modes, determining an acceptable slope angle range for the rock mass in each zone, taking a lower limit of the acceptable slope angle in each zone as an initial limit slope angle, varying azimuth limit slope angles one by one using a same incremental step distance, and obtaining orthogonal combination schemes for the limit slope angles;
step 5: based on a negative cone exclusion method, optimizing a final limit under each azimuth limit slope angle combination one by one, and obtaining parameters such as an ore amount, a waste rock amount, an average stripping ratio, and areas of the final limit, waste dump, and tailings pond for each final limit;
step 6: projecting each final limit shape one by one into the three-dimensional geological model of the mine, and deleting geological bodies inside each final limit to obtain a sequence of three-dimensional geological models for the mine final limits;
step 7: according to the rock mass zoning, intercepting slope sections in the sequence of three-dimensional geological models for the mine final limits to obtain two-dimensional slope sections for each final limit in each zone, calculating a slope instability probability for each section based on a reliability theory, and obtaining zone slope instability probability indices for all sequences of the final limit model;
step 8: according to the carbon emission calculation model for open-pit mining in step 2, calculating carbon emissions of each final limit one by one, and obtaining a carbon emission evaluation index for each limit;
step 9: determining an acceptable slope instability probability index, identifying final limit results from the sequence of three-dimensional geological models for the final limit where all the zone slope instability probability indices are higher than the acceptable slope instability probability index, and obtaining benefit evaluation indices for these final limit results;
step 10: extracting the remaining three-dimensional geological models for the final limits in step 9 as a subsequence, designing slope reinforcement schemes for zone limits in the subsequence final limits where all zone slope instability probability indices are lower than the acceptable slope instability probability index, calculating a minimum reinforcement workload required for a joint instability probability of the reinforced slope to exceed the acceptable slope instability probability index, obtaining a reinforcement workload for all final limits in the subsequence, and calculating a benefit evaluation index for each final limit in the subsequence; and
step 11: calculating comprehensive evaluation indices for all final limit sequences, comparing all comprehensive evaluation indices, and identifying a final limit with a maximum comprehensive evaluation index value as an optimization result of open-pit mine limit with simultaneous consideration of mining carbon emissions and slope safety.

Further, the mining economic and technical parameters include a final wall slope angle, a stripping ratio, a limit grade, a stripping cost, a beneficiation cost, a concentrate price, a concentrate grade, and a comprehensive recovery rate.

Further, the carbon emission calculation model for open-pit mining is as follows:

$${C}_{S} = {C}_{D} + {C}_{I} \qquad ( 1 )$$

where C_{S} is a carbon emission in the open-pit mining (t), C_{D} is a direct carbon emissions in the open-pit mining (t), and C_{I} is an indirect carbon emissions in the open-pit mining (t).

Further, the direct carbon emissions in the open-pit mining are calculated by the following formula:

$${C}_{D} = {C}_{D E} + {C}_{D O} + {C}_{D B} \qquad ( 2 )$$

where C_{DE} is a carbon emission generated by an electric energy consumption in the open-pit mining (t), C_{DO} is a carbon emission generated by a fossil energy consumption in the open-pit mining (t), and C_{DB} is a carbon emission generated by an explosive blasting in open-pit mining (t).

The carbon emission generated by the electric energy consumption in the open-pit mining is calculated by the following formula:

$${C}_{D E} = [ Q ( {e}_{W 1} + {e}_{W 2} ) + {Q}_{1} {e}_{W 3} + a {e}_{W 4} ] {η}_{e} \qquad ( 3 )$$

where Q is a total stripping amount under the final limit (t); Q₁ is A total amount of selected ore under the final limit (t); a is a mining period under the final limit (year); e_{W1} is an average electric energy consumed per unit of stripping amount (kW·h/t); e_{W2} is an average electric energy consumed per unit of stripping amount of rock or ore processed (kW·h/t); e_{W3} is an average electric energy consumed per unit of selected ore (kW·h/t); e_{W4} is a total annual average electric energy consumption of mine ancillary facilities and other equipment (kW·h/year), and ηₑ is carbon emissions generated per unit of electric energy consumption (t/(kW·h)).

The carbon emission generated by the fossil energy consumption in the open-pit mining is calculated by the following formula:

$${C}_{D O} = Q [ ( {d}_{W 1} + {d}_{W 3} ) {η}_{d 1} + ( {d}_{W 2} + {d}_{W 4} ) {η}_{d 2} ] \qquad ( 4 )$$

where d_{W1} is an average gasoline consumption per unit of stripping amount (t/t); d_{W2} is an average diesel consumption per unit of stripping amount (t/t); d_{W3} is an average gasoline consumption per unit of stripping amount of rock or ore processed (t/t); d_{W4} is an average diesel consumption per unit of stripping amount of rock or ore processed (t/t); η_{d1} is a carbon emissions generated per unit of gasoline consumption (t/t); and η_{d2} is a carbon emissions generated per unit of diesel consumption (t/t);
The carbon emission generated by the explosion in open-pit mining is calculated by the following formula:

$${C}_{D B} = Q \frac{{b}_{w} {η}_{b}}{γ} \qquad ( 5 )$$

where b_{w} is an explosive unit consumption for ore and rock blasting (t/m³); n_{b} is a carbon emission factor of the explosive (t/t); and γ is an average bulk density of ore and rock within the limit (t/m³).

Further, the indirect carbon emissions in the open-pit mining is calculated by the following formula:

$${C}_{1} = {C}_{IF} + {C}_{IR} + {C}_{IT} + {C}_{IS} \qquad ( 6 )$$

where C_{IF} is a reduction in carbon sequestration caused by land disturbance in the open pit (t); C_{IR} is a reduction in carbon sequestration caused by land disturbance in the waste dump (t); C_{IT} is a reduction in carbon sequestration caused by soil disturbance in the tailings pond (t); and C_{IS} is carbon emissions generated during a production of raw materials for open-pit mine ancillary facilities (t).

The reduction in carbon sequestration caused by land disturbance in the open pit is calculated by the following formula:

$${C}_{IF} = {\sum }_{i = 1}^{n} {A}_{F i} ( {p}_{i} {y}_{n p p} {f}_{{CO}_{2}} + {q}_{i} {h}_{s} {γ}_{s} {r}_{s o} {r}_{o c} ζ ) \qquad ( 7 )$$

where A_{Fi} is a cumulative land disturbance area in the pit in an i^{th} year (km²); pᵢ is a proportion of disturbed forest land area in the pit in the i^{th} year (%); qᵢ is a proportion of disturbed grassland area in the pit in the i^{th} year (%); yₙₚₚ is a net primary productivity of forest land (t/km²·year); f_{co}_{₂} is a CO₂ fixation coefficient of a forest land; hₛ is an average soil thickness of the disturbed grassland (m); γₛ is an average soil bulk density of the disturbed grassland (t/m³); rₛₒ is a soil organic matter content (%); r_{oc} is a proportion of carbon in soil organic matter (%); and ζ is a conversion coefficient of carbon to CO₂, which is 3.6667.

The reduction in carbon sequestration caused by land disturbance in the waste dump is calculated by the following formula:

$${C}_{I R} = {\sum }_{i = 1}^{n} \frac{{R}_{i} {k}_{w}}{{H}_{D} {γ}_{w}} {f}_{D} {p}_{i} {y}_{n p p} {f}_{{CO}_{2}} \qquad ( 8 )$$

where Rᵢ is a cumulative total amount of waste rock discharged in the i^{th} year (t); k_{w} is an expansion coefficient of waste rock after settlement of the waste dump stabilizes; γ_{w} is an average bulk density of the waste rock (t/m³); H_{D} is an average stacking height of the waste dump (m); and f_{D} is a morphological coefficient of the waste dump.

The reduction in carbon sequestration caused by soil disturbance in the tailings pond is calculated by the following formula:

$${C}_{IT} = \frac{{Q}_{2}}{{γ}_{T} {H}_{T}} ( 1 - \frac{{g}_{0}}{{g}_{p}} {r}_{p} ) ( {p}_{i}^{′} {y}_{n p p} {f}_{{CO}_{2}} + {q}_{i}^{′} {h}_{s} {γ}_{s} {r}_{s o} {r}_{o c} ζ ) \qquad ( 9 )$$

where Q₂ is a total amount of ore mined within the limit (t); gₒ is an average grade of the selected ore (%); gₚ is an average grade of concentrate (%); rₚ is a metal recovery rate of beneficiation (%); γ_{T} is an average bulk density after tailings accumulation (t/m³); H_{T} is an average depth of the tailings pond (m); pᵢ′ is a proportion of disturbed forest land area within the disturbed area of the tailings pond (%); q′ is a proportion of disturbed grassland area within the disturbed area of the tailings pond (%).

The carbon emissions generated during a production of raw materials for open-pit mine ancillary facilities are calculated by the following formula:

$${C}_{IS} = {V}_{c} {c}_{C {O}_{2}} + {V}_{b} {b}_{C {O}_{2}} \qquad ( 10 )$$

where V_{C} is a total amount of concrete used in the construction of open-pit mine ancillary facilities (m³); V_{b} is a total amount of steel used in the construction of open-pit mine ancillary facilities (m³); c_{CO}_{₂} is carbon emissions generated during the production of raw materials per unit volume of concrete (t/m³); and b_{CO}_{₂} is the carbon emissions generated during the production of raw materials per unit mass of steel (t/m³).

Further, upper and lower limits of an acceptable slope angle range for the rock mass in the zone are slope angles corresponding to a limit state and a safety state of the overall stability of the slope under a maximum slope height condition in the zone, respectively.

Further, the maximum slope height in the zone is a vertical distance between a bottom of a deepest buried ore body and a surface in the zone.

Furthermore, the acceptable slope instability probability index is selected comprehensively based on a mine scale and engineering geological and hydrogeological conditions.

Furthermore, the slope instability probability of each section is determined using a Monte Carlo simulation method.

Further, the slope reinforcement scheme is an anchor cable reinforcement type.

Further, the joint instability probability of the reinforced slope is calculated by the following formula:

$${P}_{f} ( F \vert L , θ , {X}_{t} , n ) = max \{ {P}_{f} ( {F}_{SS} - e \leq 0 ) , {P}_{f} ( {F}_{SO} - f \leq 0 ) \} \qquad ( 11 )$$

where P_{f}(F|L, θ, Xₜ, n) is a joint instability probability of the reinforced slope under different anchor cable design parameters; P_{f}(F_{SS}−e≤0) is a failure probability of anti-sliding stability; P_{f}(F_{SO}−f≤0) is a failure probability of anti-overturning stability; e and f are reduction constants for anti-sliding stability and anti-overturning stability, respectively; L is a length of an anchor cable anchorage section; θ is an angle between the anchor cable and the horizontal plane; Xₜ is a horizontal distance from an anchor cable layout point to a toe of the slope; and n is a number of rows of anchor cables.

Where the anti-sliding stability and anti-overturning stability of the reinforced slope are calculated according to Formulas (12) and (13), respectively:

$${F}_{SS} = \frac{c A + [ W ( cos β - {k}_{h} sin β ) + n T sin ( θ + β ) - U - V sin β ] tan φ}{W ( sin β + {k}_{h} cos β ) + V cos β - n T cos ( θ + β )} \qquad ( 12 )$$

$${F}_{SO} = \frac{W {X}_{W} + {\sum }_{i = 1}^{n} T ( cos θ {X}_{T i} + sin θ {X}_{T i} )}{V {X}_{V} + U {X}_{U} + {k}_{h} W {X}_{K}} \qquad ( 13 )$$

where c is a cohesion of the slope rock mass (kPa); φ is an internal friction angle of the slope rock mass) (°); A is an area of an upper sliding surface per unit width (m²); W is a self-weight of a sliding mass (kN); T is an anchoring force of the anchor cable; kₕ is an acceleration coefficient of horizontal blasting vibration; V is a resultant force of water pressure acting on a tension crack (kN); U is a resultant force of water pressure acting on a bottom sliding surface (kN); X_{W} is a horizontal distance from a point of application of the sliding body weight to the toe of the slope (m); X_{U} is a vertical distance from the point of application of the resultant water pressure on the tension crack to the toe of the slope (m); X_{U} is a shortest distance from the point of application of the resultant water pressure on the bottom sliding surface to the toe of the slope (m); and X_{K} is a vertical distance from the point of application of the sliding body weight to the toe of the slope (m).

Further, the minimum reinforcement workload required for the joint instability probability of the reinforced slope to exceed the acceptable slope instability probability index is determined by the following steps:

S1: determining a distribution range of the design parameters for each anchor cable based on geometric parameters of the slope, and substituting a uniform distribution into Formula (11) to calculate the joint instability probability of the reinforced slope under different anchor cable design parameters.

S2: excluding all combinations that the instability probability exceeds the acceptable slope instability probability index;

S3: calculating and sorting anchor cable reinforcement workload for the remaining combinations, and identifying the combination with a lowest anchor cable reinforcement workload as a minimum reinforcement workload C_{Wmin} when the joint instability probability of the reinforced slope exceeds the acceptable slope instability probability index.

Further, a comprehensive evaluation index is calculated according to the following formula:

$${C}_{Z} = {λ}_{1} {C}_{S} + {λ}_{2} {C}_{Wmin} + {λ}_{3} {C}_{P} \qquad ( 14 )$$

where C_{Z} is a comprehensive evaluation index for limit optimization considering carbon emissions and slope safety; λ₁ is a conversion coefficient for international carbon emission price; λ₂ is a conversion coefficient for slope treatment cost; λ₃ is a conversion coefficient for limit profit; and C_{P} is a value of the limit.

Compared with the existing technology, the beneficial effect of the present disclosure is as follows:

1. The method for optimizing open-pit mine limits with simultaneous consideration of mining carbon emissions and slope safety is provided, in which the economic benefits of open-pit mining, the environmental problems caused by mining, and the slope safety and stability during mining disturbance are regarded as three optimization objectives. These three objectives are simultaneously incorporated into the limit optimization method, and the influencing factors from multiple different dimensions are quantitatively considered in the final limit optimization process of the open-pit mine. In this method, the calculation accuracy and computational workload of the optimization model can be controlled by adjusting the combination scheme of azimuth limit slope angles, thereby enabling its application to the optimization of staged limits, local limits, or overall limits.

2. In the method for optimizing open-pit mine limits with simultaneous consideration of mining carbon emissions and slope safety, the carbon emissions directly and indirectly involved in the entire open-pit mining process are refined and classified, and calculation formulas of carbon emissions suitable for open-pit mines are provided. Based on these formulas, the carbon emission problems caused by open-pit mining can be quantified, and dimensional unification between carbon emission issues and mining benefits is achieved.

3. The method for optimizing open-pit mine limits with simultaneous consideration of mining carbon emissions and slope safety adopts an approach that generates a sequence of three-dimensional geological structures for final limits, thereby avoiding the problem of human intervention in slope morphology changes during the limit optimization process. Consequently, the generated final limit slope morphology exhibits random characteristics, and the conflict between conventional limit optimization methods and open-pit slope morphology optimization results is resolved.

4. In the method for optimizing open-pit mine limits with simultaneous consideration of mining carbon emissions and slope safety, the slope safety and stability issues are quantified as a function related to the workload of slope reinforcement and management, enabling the quantitative consideration of slope safety and stability factors during the limit optimization process.

### BRIEF DESCRIPTION OF THE DRAWINGS

FIG. 1 is a schematic flowchart of a method for optimizing open-pit mine limits with simultaneous consideration of mining carbon emissions and slope safety according to the present disclosure;

FIG. 2 is a schematic diagram of a flowchart for determining a minimum reinforcement workload required for a joint instability probability of the reinforced slope to exceed the acceptable slope instability probability index in a method for optimizing open-pit mine limits with simultaneous consideration of mining carbon emissions and slope safety according to the present disclosure;

FIG. 3 is a schematic diagram of geological zoning within a scope of a mining area in an embodiment according to the present disclosure;

FIG. 4 is a schematic cross-sectional view of a slope of a limit sequence in an embodiment according to the present disclosure;

FIG. 5 is a schematic diagram of a distribution trend of a limit sequence comprehensive evaluation index result in an embodiment according to the present disclosure

### DETAILED DESCRIPTION

The following clearly and completely describes the technical solutions in embodiments of the present disclosure with reference to the drawings of the embodiments. Apparently, the described embodiments are only some, but not all of the embodiments of the present disclosure. All other embodiments obtained by those of ordinary skill in the art based on the embodiments of the present disclosure without involving any creative effort shall fall within the scope of protection of the present disclosure.

### Embodiment 1

Unless otherwise defined herein, all technical and scientific terms used have the same meaning as commonly understood by one of ordinary skill in the art to which this application belongs. The terminology used herein is for the sole purpose of describing particular embodiments and is not intended to limit the application.

The objective of the present disclosure is to provide a method for optimizing open-pit mine limits with simultaneous consideration of mining carbon emissions and slope safety, wherein the influence of three factors, including limit value, slope safety, and ecological environment, can be quantitatively considered in the final limit optimization process of an open-pit mine. In this embodiment, a large open-pit iron mine is taken as an example. In order that the objectives, features and advantages of the present disclosure described above may be more readily understood, a further detailed description of the present disclosure is provided below in conjunction with the drawings and specific embodiments.

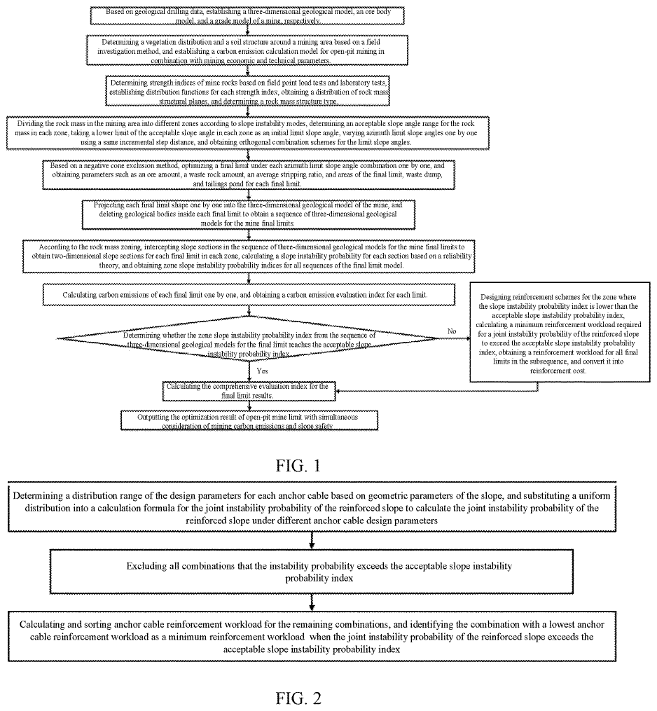

As shown in FIG. 1, the open-pit mine boundary optimization method considering both mining carbon emissions and slope safety includes the following steps:

Step 1: the three-dimensional geological model of the mine is established based on lithological data obtained from geological drilling, and the ore body model and the grade model are established based on grade data obtained from geological drilling. Due to the complex lithological conditions in the mining area, the geological model is simplified, and only the main rock mass structure is retained.

Step 2: the vegetation distribution and soil structure in the open-pit iron mine mining area are investigated; the groundwater level in the mining area is determined through drilling. The distribution of biological species within the mining area and its surroundings is determined by a sampling survey. Technical and economic parameters are determined based on mine production data. The technical approach of the present disclosure is adopted in the limit optimization of the large open-pit iron mine. The technical and economic parameters involved in the case mine are shown in Table 1.

TABLE 1
Technical and economic parameters

| Ore Mining | Rock Stripping | Rock Stripping | Concentrate |
|---|---|---|---|
| Cost (¥/t) | Cost (¥/t) | Cost (%) | Grade (%) |
| 72.00 | 17.00 | 28.13 | 65.00 |

| Ore Recovery | Beneficiation | Beneficiation | Beneficiation |
|---|---|---|---|
| Rate (%) | Recovery Rate (%) | Recovery Rate (%) | Cost (¥/t) |
| 93.30 | 80.00 | 6.00 | 70.00 |

According to field investigation and analysis, the carbon emissions generated during the mining process of the open-pit iron mine are divided into two aspects: (1) carbon emissions directly generated by energy and explosives consumed in the mine production process; (2) indirect carbon emissions caused by mine construction and production, including the reduction of carbon sequestration caused by mining and the carbon emissions generated during the production of raw materials for the construction of mine ancillary facilities. In the present disclosure, carbon emissions are used to measure the carbon emission level in the open-pit iron mine mining process, including:

The carbon emission caused by open-pit iron mine mining is calculated according to the formula C_{S}=C_{D}+C_{I};
where C_{S} is the carbon emission in the open-pit mining (t), C_{D} is the direct carbon emissions in the open-pit mining (t), and C_{I} is the indirect carbon emissions in the open-pit mining (t).

Wherein the direct carbon emission in mining is calculated according to the formula

$${C}_{D} = {C}_{D E} + {C}_{D O} + {C}_{D B} ;$$

where C_{DE} is the carbon emission generated by the electric energy consumption in the open-pit mining (t), C_{DO} is the carbon emission generated by the fossil energy consumption in the open-pit mining (t), and C_{DB} is the carbon emission generated by the explosive blasting in open-pit mining (t).

Wherein the carbon emission generated by the electric energy consumption in the mining is calculated according to the formula C_{DE}=[Q(e_{W1}+e_{W2})+Q₁e_{W3}+αe_{W4}]ηₑ;
where Q is the total stripping amount under the final limit (t); Q₁ is the total amount of selected ore under the final limit (t); a is the mining period under the final limit (year); e_{W1} is the average electric energy consumed per unit of stripping amount (kW·h/t); e_{W2} is the average electric energy consumed per unit of stripping amount of rock or ore processed (kW·h/t); e_{W3} is the average electric energy consumed per unit of selected ore (kW·h/t); e_{W4} is the total annual average electric energy consumption of mine ancillary facilities and other equipment (kW·h/year), and ηₑ is carbon emissions generated per unit of electric energy consumption (t/(kW·h)).

Wherein the carbon emission generated by the fossil energy consumption in mining is calculated according to the formula C_{DO}=Q[(d_{W1}+d_{W3}) η_{d1}+(d_{W2}+d_{W4}) η_{d2}]; where d_{W1} is the average gasoline consumption per unit of stripping amount (t/t); d_{W2} is the average diesel consumption per unit of stripping amount (t/t); d_{W3} is the average gasoline consumption per unit of stripping amount of rock or ore processed (t/t); d_{W4} is the average diesel consumption per unit of stripping amount of rock or ore processed (t/t); η_{d1} is the carbon emissions generated per unit of gasoline consumption (t/t); and η_{d2} is the carbon emissions generated per unit of diesel consumption (t/t);

Wherein the carbon emission generated by the explosive blasting in mining is calculated according to the formula

$${C}_{D B} = Q \frac{{b}_{w} {η}_{b}}{γ} ;$$

where b_{w} is the explosive unit consumption for ore and rock blasting (t/m³); η_{b} is the carbon emission factor of the explosive (t/t); and γ is the average bulk density of ore and rock within the limit (t/m³).

Wherein the indirect carbon emission in the open-pit iron mining is calculated according to the formula C_{I}=C_{IF}+C_{IR}+C_{IT}+C_{IS};
where C_{IF} is the reduction in carbon sequestration caused by land disturbance in the open pit (t); C_{IR} is the reduction in carbon sequestration caused by land disturbance in the waste dump (t); C_{IT} is the reduction in carbon sequestration caused by soil disturbance in the tailings pond (t); and C_{IS} is carbon emissions generated during the production of raw materials for open-pit mine ancillary facilities (t).

Wherein the reduction in carbon sequestration caused by land disturbance in the open pit is calculated according to the formula

$${C}_{IF} = {\sum }_{i = 1}^{n} {A}_{F i} ( {p}_{i} {y}_{n p p} {f}_{{CO}_{2}} + {q}_{i} {h}_{s} {γ}_{s} {r}_{s o} {r}_{o c} ζ ) ;$$

where A_{Fi} is the cumulative land disturbance area in the pit in an i^{th} year (km²); pᵢ is the proportion of disturbed forest land area in the pit in the i^{th} year (%); qᵢ is the proportion of disturbed grassland area in the pit in the i^{th} year (%); yₙₚₚ is the net primary productivity of forest land (t/km²·year); f_{co}_{₂} is the CO₂ fixation coefficient of the forest land; hₛ is an average soil thickness of the disturbed grassland (m); γₛ is an average soil bulk density of the disturbed grassland (t/m³); rₛₒ is the soil organic matter content (%); r_{oc} is the proportion of carbon in soil organic matter (%); and ζ is the conversion coefficient of carbon to CO₂, which is 3.6667.

Wherein the reduction in carbon sequestration caused by land disturbance in the waste dump is calculated according to the formula

$${C}_{I R} = {\sum }_{i = 1}^{n} \frac{{R}_{i} {k}_{w}}{{H}_{D} {γ}_{w}} {f}_{D} {p}_{i} {y}_{n p p} {f}_{{CO}_{2}} ;$$

where Rᵢ is the cumulative total amount of waste rock discharged in the i^{th} year (t); k_{w} is the expansion coefficient of waste rock after settlement of the waste dump stabilizes; γ_{w} is the average bulk density of the waste rock (t/m³); H_{D} is the average stacking height of the waste dump (m); and f_{D} is the morphological coefficient of the waste dump. Wherein the reduction in carbon sequestration caused by soil disturbance in the tailings pond is calculated according to the formula

$${C}_{IT} = \frac{{Q}_{2}}{{γ}_{T} {H}_{T}} ( 1 - \frac{{g}_{0}}{{g}_{p}} {r}_{p} ) ( {p}_{i}^{′} {y}_{n p p} {f}_{{CO}_{2}} + {q}_{i}^{′} {h}_{s} {γ}_{s} {r}_{s o} {r}_{o c} ζ ) ;$$

where Q₂ is the total amount of ore mined within the limit (t); gₒ is an average grade of the selected ore (%); gₚ is an average grade of concentrate (%); rₚ is the metal recovery rate of beneficiation (%); γ_{T} is the average bulk density after tailings accumulation (t/m³); H_{T} is the average depth of the tailings pond (m); pᵢ′ is the proportion of disturbed forest land area within the disturbed area of the tailings pond (%); q′ is the proportion of disturbed grassland area within the disturbed area of the tailings pond (%).

Wherein the carbon emissions generated during the production of raw materials for open-pit mine ancillary facilities are calculated according to the formula C_{IS}=V_{c}c_{CO}_{₂}+V_{b}b_{CO}_{₂};
where V_{c} is the total amount of concrete used in the construction of open-pit mine ancillary facilities (m³); V_{b} is the total amount of steel used in the construction of open-pit mine ancillary facilities (m³); c_{CO}_{₂} is the carbon emissions generated during the production of raw materials per unit volume of concrete (t/m³); and b_{CO}_{₂} is the carbon emissions generated during the production of raw materials per unit mass of steel (t/m³).

Step 3: the strength indices of mine rocks are determined based on field point load tests and laboratory tests, the distribution functions for each strength index are established, the distribution of rock mass structural planes is obtained, and the rock mass structure type is determined.

The lithological parameters involved in the case of an open-pit iron mine are shown in Table 2:

TABLE 2
Mine lithology parameter table

| | | | | | | | Uniaxial Compressive | | | Joint | |
|---|---|---|---|---|---|---|---|---|---|---|---|
| | Cohesion (MPa) | | | Internal Friction Angle (°) | | | Strength (MPa) | | | Density | Rock Mass |
| | | Standard | | | Standard | | | Standard | | (joints/ | Quality |
| Lithology | Mean | Deviation | Distribution | Mean | Deviation | Distribution | Mean | Deviation | Distribution | m³) | Grade |
| Biotite | 0.289 | 0.028 | Normal | 31.701 | 3.514 | Normal | 3.979 | 1.193 | Normal | 9.3483 | III |
| Granulite | | | | | | | | | | | |
| Mixed | 0.125 | 0.031 | Normal | 36.791 | 3.124 | Normal | 2.314 | 0.252 | Normal | 8.4765 | IV |
| Biotite | | | | | | | | | | | |
| Granulite | | | | | | | | | | | |
| Quartz | 0.093 | 0.039 | Normal | 34.204 | 2.958 | Normal | 1.023 | 1.356 | Normal | 14.7689 | IV |
| Arenite | | | | | | | | | | | |
| Granite | 0.203 | 0.042 | Normal | 34.396 | 3.673 | Normal | 2.183 | 1.652 | Normal | 8.2987 | III |
| Pegmatite | | | | | | | | | | | |

Step 4: the rock mass in the mining area is divided into different zones according to the slope instability modes, the acceptable slope angle range for the rock mass in each zone is determined, the lower limit of the acceptable slope angle in each zone is taken as the initial limit slope angle, the azimuth limit slope angles are varied one by one using the same incremental step distance, and the orthogonal combination schemes for the limit slope angles are obtained;
The upper and lower limits of the acceptable slope angle range for the rock mass in the zone are slope angles corresponding to the limit state and safety state of the overall stability of the slope under a maximum slope height condition in the zone, respectively.

The maximum slope height in the zone is the vertical distance between the bottom of the deepest buried ore body and the surface in the zone.

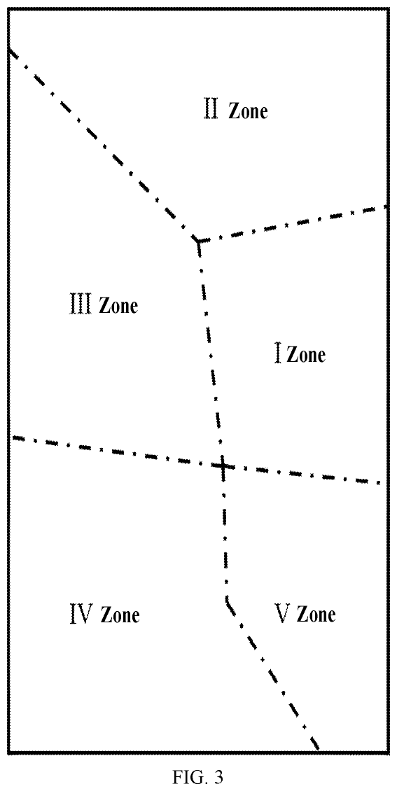

The geological division of the case open-pit iron mine is shown in FIG. 3. The acceptable range of slope angle in each zone is shown in Table 3, and the increment step of slope angle change in each azimuth is 1°.

TABLE 3
Acceptable slope angle ranges for limit slopes in each azimuth

| Azimuth | 30° | 102.5° | 180° | 275° | 342.5° |
|---|---|---|---|---|---|
| Upper Limit of | 43° | 44° | 51° | 49° | 44° |
| Acceptable Slope Angle | | | | | |
| Lower Limit of | 35° | 36° | 44° | 42° | 36° |
| Acceptable Slope Angle | | | | | |

In the embodiment, the 180° azimuth (IV Zone) of the case open-pit iron mine is taken as an example to design the azimuth limit slope angle combination scheme. The limit slope angles of other azimuths are fixed, and the incremental step is set to 1°. Starting from the lower limit of the acceptable slope angle and ending at the upper limit of the acceptable slope angle, a total of eight limit slope angle combination schemes are designed.

Step 5: based on the negative cone exclusion method, the final limit under each azimuth slope angle combination is calculated one by one, and parameters such as ore amount, waste rock amount, average stripping ratio, and limit area under each final limit are obtained.

The result parameters of the case open-pit iron mine under the combination scheme of eight azimuth limit slope angles are shown in Table 4.

TABLE 4
The final limit optimization results under each slope angle scheme

| | Slope Angle | | | Average | | Limit |
|---|---|---|---|---|---|---|
| Scheme | at 180° | Ore Amount | Rock Amount | Stripping | Average | Area |
| No. | Azimuth | (10⁴t) | (10⁴t) | Ratio | Ore Grade | (km²) |
| 1 | 44° | 57502.5994 | 180570.6502 | 3.1094 | 0.258980 | 3.9025 |
| 2 | 45° | 57450.6723 | 179953.5235 | 3.1015 | 0.258978 | 3.886875 |
| 3 | 46° | 57202.5228 | 178212.3651 | 3.0848 | 0.258949 | 3.8625 |
| 4 | 47° | 57209.7129 | 178065.4616 | 3.0819 | 0.258954 | 3.856875 |
| 5 | 48° | 57206.9301 | 177791.3731 | 3.0773 | 0.258957 | 3.849375 |
| 6 | 49° | 57160.4354 | 177263.4573 | 3.0706 | 0.258937 | 3.843125 |
| 7 | 50° | 57328.5728 | 178111.1531 | 3.0763 | 0.258946 | 3.851875 |
| 8 | 51° | 57246.9210 | 177529.0566 | 3.0706 | 0.258946 | 3.845 |

Step 6: each final limit shape is projected one by one into the three-dimensional geological model of the mine, and the geological bodies inside each final limit are deleted to obtain a sequence of three-dimensional geological models of the mine final limits when mining reaches the final limit.

In the case of an open-pit iron mine, 3DMine software is used to complete this step.

Step 7: according to the rock mass zoning, the slope sections are intercepted in the sequence of three-dimensional geological models for the mine final limits to obtain two-dimensional slope sections for each final limit in each zone, the slope instability probability for each section is calculated based on the reliability theory, and the zone slope instability probability indices for all sequences of the final limit model are obtained;

The slope instability probability of each section is determined using the Monte Carlo simulation method.

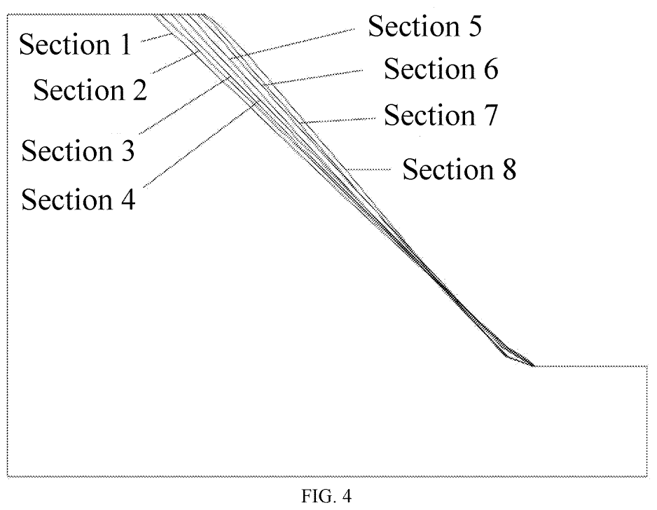

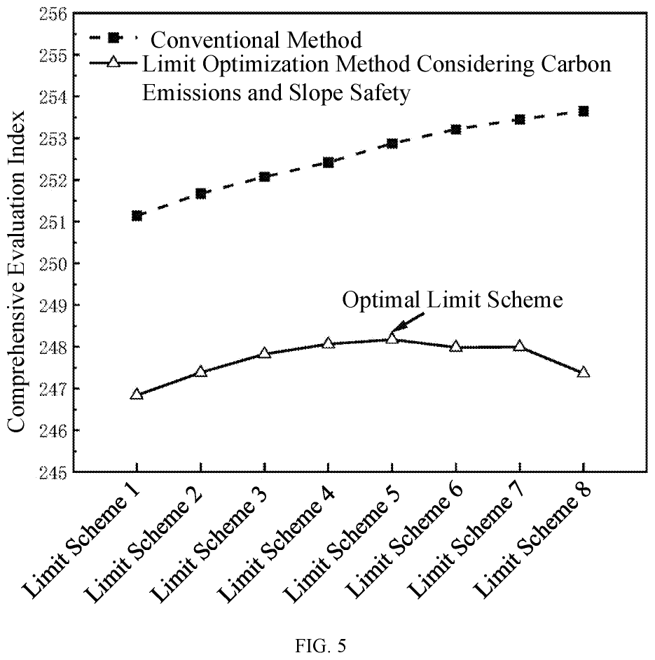

In the case of the open-pit iron mine, the slope section sections of the above eight schemes are shown in FIG. 4. In this embodiment, because the slope angles in other azimuths are fixed, only the calculation results of the slope section instability probability for the eight schemes in the 180° azimuth (Zone IV) are provided, as shown in Table 5.

TABLE 5
The calculation results of slope section instability probability of each scheme

| Scheme No. | 1 | 2 | 3 | 4 | 5 | 6 | 7 | 8 |
|---|---|---|---|---|---|---|---|---|
| Slope Instability | 0.0008 | 0.0020 | 0.0026 | 0.0108 | 0.1004 | 0.2301 | 0.4803 | 0.7650 |
| Probability | | | | | | | | |

Step 8: according to the carbon emission calculation model for open-pit mining in step 2, the carbon emissions of each final limit are calculated one by one, and the carbon emission evaluation index for each limit is obtained.

The carbon emission results of eight sample schemes of case open-pit iron mine are shown in Table 6.

TABLE 6
Carbon emissions results of each scheme

| Scheme No. | 1 | 2 | 3 | 4 | 5 | 6 | 7 | 8 |
|---|---|---|---|---|---|---|---|---|
| Direct | 946719.41 | 944102.79 | 936283.42 | 935744.63 | 934669.65 | 932421.03 | 936430.20 | 933822.36 |
| Carbon | | | | | | | | |
| Emissions | | | | | | | | |
| (t) | | | | | | | | |
| Indirect | 283227.29 | 281903.73 | 278588.64 | 278283.14 | 277771.43 | 276961.77 | 278656.31 | 277615.90 |
| Carbon | | | | | | | | |
| Emissions | | | | | | | | |
| (t) | | | | | | | | |
| Carbon | 1229946.69 | 1226006.52 | 1214872.07 | 1214027.77 | 1212441.0 | 1209382.80 | 1215086.51 | 1211438.26 |
| Emissions | | | | | | | | |
| (t) | | | | | | | | |

Step 9: the acceptable slope instability probability index is determined, and the final limit results from the sequence of three-dimensional geological models for the final limit are identified where all the zone slope instability probability indices are higher than the acceptable slope instability probability index, and the benefit evaluation indices for these final limit results are obtained.

The acceptable slope instability probability index is selected comprehensively based on the mine scale and engineering geological and hydrogeological conditions.

The acceptable slope instability probability index of the case open-pit iron mine is 0.0062.

Step 10: the remaining three-dimensional geological models for the final limits in step 9 are extracted as the subsequence, the slope reinforcement schemes are designed for zone limits in the subsequence final limits where all zone slope instability probability indices are lower than the acceptable slope instability probability index. The minimum reinforcement workload required for the joint instability probability of the reinforced slope to exceed the acceptable slope instability probability index is calculated, the reinforcement workload for all final limits in the subsequence is obtained, and the benefit evaluation index for each final limit in the subsequence is calculated.

The slope reinforcement scheme is an anchor cable reinforcement type.

The minimum reinforcement workload required for the joint instability probability of the reinforced slope to exceed the acceptable slope instability probability index is determined according to the steps shown in FIG. 2:

S1: the distribution range of the design parameters for each anchor cable is determined based on geometric parameters of the slope, and the uniform distribution is substituted into the Formula P_{f}(F|L, θ, Xₜ, n)=max{P_{f}(F_{SS}−e≤0), P_{f}(F_{SO}−f≤0)} to calculate the joint instability probability of the reinforced slope under different anchor cable design parameters;
where P_{f}(F|L, θ, Xₜ, n) is the joint instability probability of the reinforced slope under different anchor cable design parameters; P_{f}(F_{SS}−e≤0) is the failure probability of anti-sliding stability; P_{f}(F_{SO}−f≤0) is the failure probability of anti-overturning stability; e and f are reduction constants for anti-sliding stability and anti-overturning stability, respectively; L is the length of an anchor cable anchorage section; θ is an angle between the anchor cable and the horizontal plane; Xₜ is the horizontal distance from an anchor cable layout point to the toe of the slope; and n is the number of rows of anchor cables.

The anti-sliding stability of the reinforced slope is calculated according to the formula

$${F}_{SS} = \frac{c A + [ W ( cos β - {k}_{h} sin β ) + nT sin ( θ + β ) - U - V sin β ] tan φ}{W ( sin β + {k}_{h} cos β ) + V cos β - n T cos ( θ + β )} ,$$

and the anti-overturning stability of the reinforced slope is calculated according to the formula

$${F}_{SO} = \frac{W {X}_{W} + {\sum }_{i = 1}^{n} T ( cos θ {X}_{T i} + sin θ {X}_{T i} )}{V {X}_{V} + U {X}_{U} + {k}_{h} W {X}_{K}} ;$$

where c is the cohesion of the slope rock mass (kPa); φ is the internal friction angle of the slope rock mass) (°; A is the area of an upper sliding surface per unit width (m²); W is the self-weight of the sliding mass (kN); T is the anchoring force of the anchor cable; kₕ is the acceleration coefficient of horizontal blasting vibration; V is the resultant force of water pressure acting on the tension crack (kN); U is the resultant force of water pressure acting on the bottom sliding surface (kN); X_{W} is the horizontal distance from the point of application of the sliding body weight to the toe of the slope (m); X_{U} is the vertical distance from the point of application of the resultant water pressure on the tension crack to the toe of the slope (m); X_{U} is the shortest distance from the point of application of the resultant water pressure on the bottom sliding surface to the toe of the slope (m); and X_{K} is the vertical distance from the point of application of the sliding body weight to the toe of the slope (m).

S2: all combinations that the instability probability exceeds the acceptable slope instability probability index are excluded;

S3: the anchor cable reinforcement workload for the remaining combinations is calculated and sorted, and the combination with the lowest anchor cable reinforcement workload is identified as the minimum reinforcement workload C_{Wmin} when the joint instability probability of the reinforced slope exceeds the acceptable slope instability probability index.

The minimum reinforcement workload of the eight sample schemes of the case open-pit iron mine when the acceptable slope instability probability index is reached is shown in Table 7.

Table 7 The minimum reinforcement workload when each scheme reaches the acceptable slope instability probability index

| Scheme No. | 1 | 2 | 3 | 4 | 5 | 6 | 7 | 8 |
|---|---|---|---|---|---|---|---|---|
| Unreinforced | 0.0008 | 0.0020 | 0.0026 | 0.0108 | 0.1004 | 0.2301 | 0.4803 | 0.7650 |
| Slope | | | | | | | | |
| Instability | | | | | | | | |
| Probability | | | | | | | | |
| Minimum | 0 | 0 | 0 | 52827.67 | 228320.28 | 497268.33 | 602483.32 | 1023565.98 |
| Reinforcement | | | | | | | | |
| Workload | | | | | | | | |
| C_{Wmin} (m) | | | | | | | | |
| Reinforced | 0.0008 | 0.0020 | 0.0026 | 0.0060 | 0.0060 | 0.0060 | 0.0060 | 0.0060 |
| Slope | | | | | | | | |
| Instability | | | | | | | | |
| Probability | | | | | | | | |

Step 11: the comprehensive evaluation indices for all final limit sequences are calculated, all comprehensive evaluation indices are compared, and the final limit with the maximum comprehensive evaluation index value is identified as the optimization result of the open-pit mine limit with simultaneous consideration of mining carbon emissions and slope safety. The comprehensive evaluation index is calculated according to the formula C_{Z}=λ₁C_{S}+λ₂C_{Wmin}+13 Cₚ;
where C_{Z} is the comprehensive evaluation index for limit optimization considering carbon emissions and slope safety; λ₁ is the conversion coefficient for international carbon emission price; λ₂ is the conversion coefficient for slope treatment cost; λ₃ is the conversion coefficient for limit profit; and C_{P} is the value of the limit.

The comprehensive evaluation results of the above eight schemes for the case open-pit iron mine are shown in FIG. 5. The results indicate that when the two factors of carbon emissions and slope stability caused by open-pit mining are not considered, the comprehensive evaluation index of open-pit mining gradually increases as the regional slope angle increases, and the optimal solution can not be obtained. In contrast, the comprehensive evaluation index of open-pit mining obtained by the present disclosure not only simultaneously considers the two factors of carbon emissions and slope stability associated with open-pit mining, but also yields the optimal limit. The optimal limit result corresponds to Scheme No. 5, as shown in FIG. 5. The present disclosure achieves the simultaneous incorporation of three optimization objectives, including the economic benefits of open-pit mining, the environmental problems caused by mining, and the safety and stability of the slope during mining disturbance, into the limit optimization method, and the optimal limit sequence is evaluated through a comprehensive evaluation index system. The random regional or overall slope morphology generation is achieved, and the conflict between slope geometry optimization results and limit optimization results is resolved.

Any technical details not mentioned in the above methods may be achieved by adopting or referencing existing technologies.

It should be noted that, following the guidance provided in this specification, those skilled in the art may also make various modifications, such as equivalent modifications or obvious variations. All such modifications should fall within the scope of the present disclosure.

What is claimed is:

1. A method for optimizing open-pit mine limits with simultaneous consideration of mining carbon emissions and slope safety, employing the following steps:
step 1: based on geological drilling data, establishing a three-dimensional geological model, an ore body model, and a grade model of a mine, respectively;
step 2: determining a vegetation distribution and a soil structure around a mining area based on a field investigation method, and establishing a carbon emission calculation model for open-pit mining in combination with mining economic and technical parameters;
step 3: determining strength indices of mine rocks based on field point load tests and laboratory tests, establishing distribution functions for each strength index, obtaining a distribution of rock mass structural planes, and determining a rock mass structure type;
step 4: dividing the rock mass in the mining area into different zones according to slope instability modes, determining an acceptable slope angle range for the rock mass in each zone, taking a lower limit of the acceptable slope angle in each zone as an initial limit slope angle, varying azimuth limit slope angles one by one using a same incremental step distance, and obtaining orthogonal combination schemes for the limit slope angles;
step 5: based on a negative cone exclusion method, optimizing a final limit under each azimuth limit slope angle combination one by one, and obtaining parameters such as an ore amount, a waste rock amount, an average stripping ratio, and areas of the final limit, waste dump, and tailings pond for each final limit;
step 6: projecting each final limit shape one by one into the three-dimensional geological model of the mine, and deleting geological bodies inside each final limit to obtain a sequence of three-dimensional geological models for the mine final limits;
step 7: according to the rock mass zoning, intercepting slope sections in the sequence of three-dimensional geological models for the mine final limits to obtain two-dimensional slope sections for each final limit in each zone, calculating a slope instability probability for each section based on a reliability theory, and obtaining zone slope instability probability indices for all sequences of the final limit model;
step 8: according to the carbon emission calculation model for open-pit mining in step 2, calculating carbon emissions of each final limit one by one, and obtaining a carbon emission evaluation index for each limit;
step 9: determining an acceptable slope instability probability index, identifying final limit results from the sequence of three-dimensional geological models for the final limit where all the zone slope instability probability indices are higher than the acceptable slope instability probability index, and obtaining benefit evaluation indices for these final limit results;
step 10: extracting remaining three-dimensional geological models for the final limits in step 9 as a subsequence, designing slope reinforcement schemes for zone limits in the subsequence final limits where all zone slope instability probability indices are lower than the acceptable slope instability probability index, calculating a minimum reinforcement workload required for a joint instability probability of the reinforced slope to exceed the acceptable slope instability probability index, obtaining a reinforcement workload for all final limits in the subsequence, and calculating a benefit evaluation index for each final limit in the subsequence; and
step 11: calculating comprehensive evaluation indices for all final limit sequences, comparing all comprehensive evaluation indices, and identifying a final limit with a maximum comprehensive evaluation index value as an optimization result of open-pit mine limit with simultaneous consideration of mining carbon emissions and slope safety;
wherein a comprehensive evaluation index for the final limit sequence specifically comprises:
the comprehensive evaluation index for the final limit sequence is determined using a formula C_{Z}=λ₁C_{S}+λ₂C_{Wmin}+λ₃C_{P};
where C_{Z} is a comprehensive evaluation index for limit optimization considering carbon emissions and slope safety; λ₁ is a conversion coefficient for international carbon emission price; C_{S} is carbon emissions in the open-pit mining (t); λ₂ is a conversion coefficient for slope treatment cost; C_{Wmin} is a minimum reinforcement workload when the joint instability probability of the reinforced slope exceeds the acceptable slope instability probability index (m); λ₃ is a conversion coefficient for limit profit; and C_{P} is a value of the limit.

2. The method for optimizing open-pit mine limits with simultaneous consideration of mining carbon emissions and slope safety according to claim 1, wherein the carbon emission calculation model for open-pit mining specifically comprises:
wherein the carbon emission calculation model for open-pit mining is determined using a formula C_{S}=C_{D}+C_{I};
where C_{S} is the carbon emissions in the open-pit mining (t), C_{D} is direct carbon emissions in the open-pit mining (t), and C_{I} is indirect carbon emissions in the open-pit mining (t);
wherein the direct carbon emissions in the open-pit mining are determined using a formula
$${C}_{D} = {C}_{D E} + {C}_{D O} + {C}_{D B} ;$$
where C_{DE} is a carbon emission generated by an electric energy consumption in the open-pit mining (t), C_{DO} is a carbon emission generated by a fossil energy consumption in the open-pit mining (t), and C_{DB} is a carbon emission generated by an explosive blasting in open-pit mining (t);
wherein the carbon emission generated by the electric energy consumption in the open-pit mining is determined using a formula C_{DE}=[Q(e_{W1}+e_{W2})+Q₁e_{W3}+αe_{W4}]ηₑ;
where Q is a total stripping amount under the final limit (t); Q₁ is a total amount of selected ore under the final limit (t); a is a mining period under the final limit (year); e_{W1} is an average electric energy consumed per unit of stripping amount (kW·h/t); e_{W2} is an average electric energy consumed per unit of stripping amount of rock or ore processed (kW·h/t); e_{W3} is an average electric energy consumed per unit of selected ore (kW·h/t); e_{W4} is a total annual average electric energy consumption of mine ancillary facilities and other equipment (kW·h/year), and ηₑ is carbon emissions generated per unit of electric energy consumption (t/(kW·h));
wherein the carbon emission generated by the fossil energy consumption in the open-pit mining is determined using a formula C_{DO}=Q[(d_{W1}+d_{W3}) η_{d1}+(d_{W2}+d_{W4}) η_{d2}];
where d_{W1} is an average gasoline consumption per unit of stripping amount (t/t); d_{W2} is an average diesel consumption per unit of stripping amount (t/t); d_{W3} is an average gasoline consumption per unit of stripping amount of rock or ore processed (t/t); d_{W4} is an average diesel consumption per unit of stripping amount of rock or ore processed (t/t); η_{d1} is a carbon emissions generated per unit of gasoline consumption (t/t); and η_{d2} is a carbon emissions generated per unit of diesel consumption (t/t);
wherein the carbon emission generated by the explosive blasting in open-pit mining is determined using a formula
$${C}_{D B} = Q \frac{{b}_{w} {η}_{b}}{γ} ;$$
where b_{w} is an explosive unit consumption for ore and rock blasting (t/m³); η_{b} is a carbon emission factor of the explosive (t/t); and γ is an average bulk density of ore and rock within the limit (t/m³);
wherein the indirect carbon emissions in the open-pit mining is determined using a formula
$${C}_{I} = {C}_{IF} + {C}_{IR} + {C}_{IT} + {C}_{IS} ;$$
where C_{IF} is a reduction in carbon sequestration caused by land disturbance in the open pit (t); C_{IR} is a reduction in carbon sequestration caused by land disturbance in the waste dump (t); C_{IT} is a reduction in carbon sequestration caused by soil disturbance in the tailings pond (t); and C_{IS} is carbon emissions generated during a production of raw materials for open-pit mine ancillary facilities (t);
wherein the reduction in carbon sequestration caused by land disturbance in the open pit is determined using a formula
$${C}_{IF} = {\sum }_{i = 1}^{n} {A}_{F i} ( {p}_{i} {y}_{n p p} {f}_{{CO}_{2}} + {q}_{i} {h}_{s} {γ}_{s} {r}_{s o} {r}_{o c} ζ ) ;$$
where A_{Fi} is a cumulative land disturbance area in the pit in an i^{th} year (km²); pᵢ is a proportion of disturbed forest land area in the pit in the i^{th} year (%); qᵢ is a proportion of disturbed grassland area in the pit in the i^{th} year (%); yₙₚₚ is a net primary productivity of forest land (t/km² year); f_{CO}_{₂} is a CO₂ fixation coefficient of a forest land; hₛ is an average soil thickness of the disturbed grassland (m); γₛ is an average soil bulk density of the disturbed grassland (t/m³); rₛₒ is a soil organic matter content (%); r_{oc} is a proportion of carbon in soil organic matter (%); and ζ is a conversion coefficient of carbon to CO₂, with a value of 3.6667;
wherein the reduction in carbon sequestration caused by land disturbance in the waste dump is determined using a formula
$${C}_{I R} = {\sum }_{i = 1}^{n} \frac{{R}_{i} {k}_{w}}{{H}_{D} {γ}_{w}} {f}_{D} {p}_{i} {y}_{n p p} {f}_{{CO}_{2}} ;$$
where Rᵢ is a cumulative total amount of waste rock discharged in the i^{th} year (t); k_{w} is an expansion coefficient of waste rock after settlement of the waste dump stabilizes; γ_{w} is an average bulk density of the waste rock (t/m³); H_{D} is an average stacking height of the waste dump (m); and f_{D} is a morphological coefficient of the waste dump;
wherein the reduction in carbon sequestration caused by soil disturbance in the tailings pond is determined using a formula
$${C}_{IT} = \frac{{Q}_{2}}{{γ}_{T} {H}_{T}} ( 1 - \frac{{g}_{0}}{{g}_{p}} {r}_{p} ) ( p {y}_{n p p} {f}_{{CO}_{2}} + {qh}_{s} {γ}_{s} {r}_{s o} {r}_{o c} ζ ) ;$$
where Q₂ is a total amount of ore mined within the limit (t); gₒ is an average grade of the selected ore (%); gₚ is an average grade of concentrate (%); rₚ is a metal recovery rate of beneficiation (%); γ_{T} is an average bulk density after tailings accumulation (t/m³); H_{T} is an average depth of the tailings pond (m); pᵢ′ is a proportion of disturbed forest land area within the disturbed area of the tailings pond (%); q′ is a proportion of disturbed grassland area within the disturbed area of the tailings pond (%);
wherein the carbon emissions generated during a production of raw materials for open-pit mine ancillary facilities are determined using a formula C_{I}=V_{c}c_{CO}_{₂}+V_{b}b_{CO}_{₂};
where V_{C} is a total amount of concrete used in the construction of open-pit mine ancillary facilities (m³); V_{b} is a total amount of steel used in the construction of open-pit mine ancillary facilities (m³); c_{CO}_{₂} is carbon emissions generated during the production of raw materials per unit volume of concrete (t/m³); and b_{CO}_{₂} is the carbon emissions generated during the production of raw materials per unit mass of steel (t/m³).

3. The method for optimizing open-pit mine limits with simultaneous consideration of mining carbon emissions and slope safety according to claim 1, wherein the joint instability probability of the reinforced slope specifically comprises:
the joint instability probability of the reinforced slope is determined using a formula
$${P}_{f} ( F \vert L , θ , {X}_{t} , n ) = max \{ {P}_{f} ( {F}_{SS} - e \leq 0 ) , {P}_{f} ( {F}_{SO} - f \leq 0 ) \} ;$$
where P_{f}(F|L, θ,Xₜ, n) is a joint instability probability of the reinforced slope under different anchor cable design parameters; P_{f}(F_{SS}−e≤0) is a failure probability of anti-sliding stability; P_{f}(F_{SO}−f≤0) is a failure probability of anti-overturning stability; e and f are reduction constants for anti-sliding stability and anti-overturning stability, respectively; L is a length of an anchor cable anchorage section; θ is an angle between the anchor cable and the horizontal plane; Xₜ is a horizontal distance from an anchor cable layout point to a toe of the slope; and n is a number of rows of anchor cables.

4. The method for optimizing open-pit mine limits with simultaneous consideration of mining carbon emissions and slope safety according to claim 1, wherein the minimum reinforcement workload required for the joint instability probability of the reinforced slope to exceed the acceptable slope instability probability index is determined by the following steps:
S1: determining a distribution range of the design parameters for each anchor cable based on geometric parameters of the slope, and substituting a uniform distribution into a calculation formula for the joint instability probability of the reinforced slope to calculate the joint instability probability of the reinforced slope under different anchor cable design parameters;
S2: excluding all combinations that the instability probability exceeds the acceptable slope instability probability index; and
S3: calculating and sorting anchor cable reinforcement workload for the remaining combinations, and identifying the combination with a lowest anchor cable reinforcement workload as a minimum reinforcement workload C_{Wmin} when the joint instability probability of the reinforced slope exceeds the acceptable slope instability probability index.

5. The method for optimizing open-pit mine limits with simultaneous consideration of mining carbon emissions and slope safety according to claim 1, wherein the mining economic and technical parameters comprise a final wall slope angle, a stripping ratio, a limit grade, a stripping cost, a beneficiation cost, a concentrate price, a concentrate grade and a comprehensive recovery rate;
wherein upper and lower limits of an acceptable slope angle range for the rock mass in the zone are slope angles corresponding to a limit state and a safety state of the overall stability of the slope under a maximum slope height condition in the zone, respectively;
wherein the maximum slope height in the zone is a vertical distance between a bottom of a deepest buried ore body and a surface in the zone;
wherein the acceptable slope instability probability index is selected comprehensively based on a mine scale and engineering geological and hydrogeological conditions;
wherein the slope instability probability of each section is determined using a Monte Carlo simulation method;
wherein the slope reinforcement scheme is an anchor cable reinforcement type.

6. The method for optimizing open-pit mine limits with simultaneous consideration of mining carbon emissions and slope safety according to claim 3, wherein the anti-sliding stability and anti-overturning stability of the reinforced slope specifically comprise:
the anti-sliding stability of the reinforced slope is determined using a formula F_{SS}=
$$\frac{c A + [ W ( cos β - {k}_{h} sin β ) + n T sin ( θ + β ) - U - V sin β ] tan φ}{W ( sin β + {k}_{h} cos β ) + V cos β - n T cos ( θ + β )} ;$$
and the anti-overturning stability of the reinforced slope is determined using a formula
$${F}_{SO} = \frac{W {X}_{W} + {\sum }_{i = 1}^{n} T ( cos θ {X}_{T i} + sin θ {X}_{T i} )}{V {X}_{V} + U {X}_{U} + {k}_{h} W {X}_{K}} ;$$
where c is a cohesion of the slope rock mass (kPa); φ is an internal friction angle of the slope rock mass) (°); A is an area of an upper sliding surface per unit width (m²); W is a self-weight of a sliding mass (kN); T is an anchoring force of the anchor cable; kₕ is an acceleration coefficient of horizontal blasting vibration; V is a resultant force of water pressure acting on a tension crack (kN); U is a resultant force of water pressure acting on a bottom sliding surface (kN); X_{W} is a horizontal distance from a point of application of the sliding body weight to the toe of the slope (m); X_{U} is a vertical distance from the point of application of the resultant water pressure on the tension crack to the toe of the slope (m); X_{U} is a shortest distance from the point of application of the resultant water pressure on the bottom sliding surface to the toe of the slope (m); and X_{K} is a vertical distance from the point of application of the sliding body weight to the toe of the slope (m).
